(19) United States
(12) Patent Application Publication
(10) Pub. No.: US 2025/0081833 A1
(43) Pub. Date: Mar. 6, 2025

(54) MANUFACTURING METHOD OF PEROVSKITE LIGHT-EMITTING DEVICE USING MECHANICAL CUTTING TECHNOLOGY AND PEROVSKITE LIGHT-EMITTING DEVICE MANUFACTURED THROUGH THE SAME

(71) Applicants: KOREA ADVANCED INSTITUTE OF SCIENCE AND TECHNOLOGY, Daejeon (KR); Seoul National University R&DB Foundation, Seoul (KR)

(72) Inventors: Byungha SHIN, Daejeon (KR); Joonyun KIM, Daejeon (KR); Jinu PARK, Daejeon (KR); Yun Seog LEE, Seoul (KR); Young Ho CHU, Seoul (KR); Kyung Tak YOON, Seoul (KR); Sunggun YOON, Seoul (KR); Ki Tae PARK, Seoul (KR)

(21) Appl. No.: 18/820,483

(22) Filed: Aug. 30, 2024

(30) Foreign Application Priority Data
Aug. 30, 2023 (KR) 10-2023-0114642

(51) Int. Cl. H10K 71/20; C07F 7/24; C09K 11/06; G03F 7/40; H10K 50/11; H10K 50/15; H10K 59/00; H10K 71/50; H10K 85/10; H10K 85/50

(52) U.S. Cl. CPC H10K 71/233; C07F 7/24; C09K 11/06; G03F 7/40; H10K 59/771; H10K 71/50; H10K 85/1135; H10K 85/50; H10K 50/11; H10K 50/15

(57) ABSTRACT

Disclosed are a method of manufacturing a light-emitting device using mechanical cutting technology and a light-emitting device manufactured through the method, and an embodiment provides a method of implementing a pixelated light-emitting device.

### CROSS-REFERENCE TO RELATED APPLICATION

This application claims priority to and the benefit of Korean Patent Application No. 10-2023-0114642 filed in the Korean Intellectual Property Office on Aug. 30, 2023, and Korean Patent Application No. filed in the Korean Intellectual Property Office on, the entire contents of which are incorporated herein by reference.

### BACKGROUND OF THE INVENTION

### (a) Field of the Invention

A method of manufacturing a light-emitting device using mechanical cutting technology and a light-emitting device manufactured through the method are disclosed.

### (b) Description of the Related Art

A display device including a light-emitting device has a plurality of pixels consisting of subpixels such as red (R), green (G), and blue (B), and in each subpixel, a pixel circuit of the light-emitting device is located.

Herein, the light-emitting device includes an anode, a cathode, and a light emitting layer disposed between the anode and cathode, and the pixel circuit includes at least two thin film transistors and at least one capacitor.

A method of pixelating the light-emitting device, which may correspond to the pixels or the subpixels, is required.

### SUMMARY OF THE INVENTION

An embodiment provides a method of implementing a pixelated light-emitting device.

An embodiment provides a method of implementing a pixelated light-emitting device using the soft mechanical properties of a two-dimensional material.

According to an embodiment, a pixelated light-emitting device can be implemented with a high pixel density.

### BRIEF DESCRIPTION OF THE DRAWINGS

FIGS. 1 to 3 are schematic views showing light-emitting devices manufactured according to embodiments.

FIG. 4 is a schematic view showing a method of manufacturing a pixelated template in an embodiment.

FIG. 5 is a view showing the emission peak according to n of the Ruddlesden-Popper perovskite according to an embodiment.

FIG. 6 is a schematic view showing a process for transferring and exfoliating a Ruddlesden-Popper perovskite bulk single crystal layer according to an embodiment.

FIG. 7 is a view showing a color difference expressed according to the thickness of the exfoliated Ruddlesden-Popper perovskite single crystal layer according to an embodiment.

FIG. 8 is a schematic view illustrating a process for transferring two-dimensional material to a pixelated template in an embodiment.

FIG. 9 is an OM photograph of a two-dimensional material pixel array according to an embodiment.

FIG. 10 is a process flowchart for manufacturing a perovskite light-emitting device according to an embodiment.

### DETAILED DESCRIPTION OF THE EMBODIMENTS

Hereinafter, a light-emitting device according to an embodiment of the present invention will be described in detail with reference to the attached drawings. However, this is presented as an example, and the present invention is not limited thereby, and the present invention is only defined by the scope of the claims to be described later.

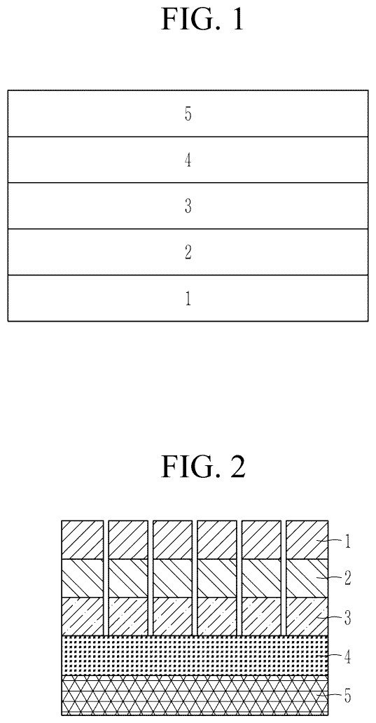

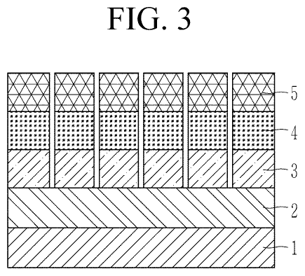

FIGS. 1 to 3 are schematic views showing light-emitting devices manufactured according to embodiments, which includes both a forward structure and an inverse structure.

### (Method for Manufacturing Light-Emitting Devices)

An embodiment provides a method for manufacturing a light-emitting device that includes preparing a pixelated template having convex portions and concave portions; transferring two-dimensional material to the pixelated template, thereby selectively removing the two-dimensional material on the concave portion and obtaining a first stack of two-dimensional material pixel arrays deposited on the convex portion; and detaching the two-dimensional material pixel array from the first stack and placing the two-dimensional material pixel array between a first electrode on which a first functional layer is deposited and a second electrode on which a second functional layer is deposited.

An embodiment provides a method of implementing a pixelated light-emitting device at high density by utilizing the soft mechanical properties of two-dimensional materials.

### Pixelated Template

The pixelated template may be a silicon substrate having convex portions and concave portions.

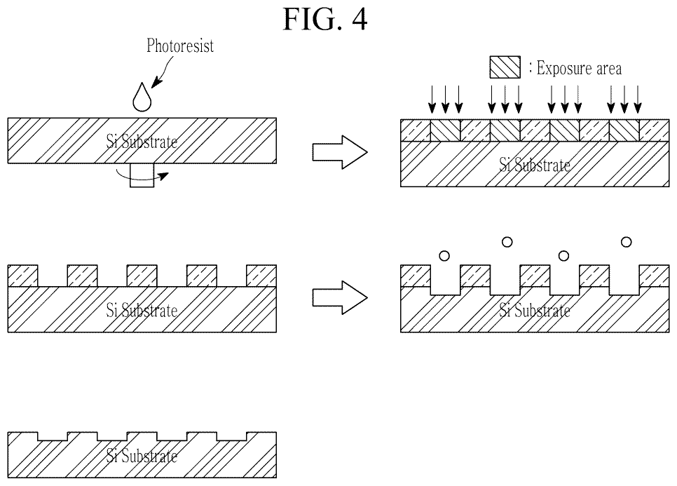

Specifically, FIG. 4 is a schematic view illustrating a method of manufacturing a pixelated template in an embodiment.

Referring to FIG. 4, the pixelated template may be manufactured by coating photoresist on a silicon substrate; exposing a selective region of the photoresist through photolithography; and removing photoresist from the exposed region; removing the photoresist in the exposed region and then etching the photoresist in the remaining region.

The etching of the photoresist in the remaining region may be performed using DRIE (Deep Reactive Ion Etching). Additionally, after etching the photoresist in the remaining region, removing of the remaining photoresist may be further included.

### Two-Dimensional Material

The two-dimensional material corresponds to a material that has a layered structure and has soft mechanical properties while exhibiting luminescent properties.

Specifically, the two-dimensional material may include exfoliated Ruddlesden-Popper perovskite single crystal layer, graphene, bulk graphene, mica, molybdenum disulfide MoS₂, or combinations thereof.

### Exfoliated Ruddlesden-Popper Perovskite Single Crystal Layer

The exfoliated Ruddlesden-Popper perovskite single crystal layer may include Ruddlesden-Popper perovskite represented by Chemical Formula 1:

R₂Aₙ₋₁PbₙX₃ₙ₊₁ [Chemical Formula 1]

In Chemical Formula 1,

R is a C1 to C30 alkyl ammonium cation;

A is a cation selected from a methylammonium cation (MA⁺), a formamidinium cation (FA⁺), and a cesium cation (Cs⁺);

X is a halogen selected from I, Br, and Cl; and

n is an integer from 1 to 10.

### Manufacturing Method of Exfoliated Ruddlesden-Popper Perovskite Single Crystal Layer

The exfoliated Ruddlesden-Popper perovskite single crystal layer may be manufactured by transferring a Ruddlesden-Popper perovskite (RPP) bulk single crystal layer onto a hydrophilic conductive polymer substrate; and exfoliating the transferred Ruddlesden-Popper perovskite bulk single crystal layer to form an exfoliated Ruddlesden-Popper perovskite single crystal layer.

As for perovskite (ABX₃) with a 3-dimensional crystal structure, a bandgap is possible to control by mixing halide (i.e., using two or more types of halides as X). In contrast, as for the Ruddlesden-Popper perovskite, because the bandgap may be controlled by even not mixing the halide (i.e., even by using one type of halide as X), spectrum instability issues occurring in a case of mixing the halide may be solved.

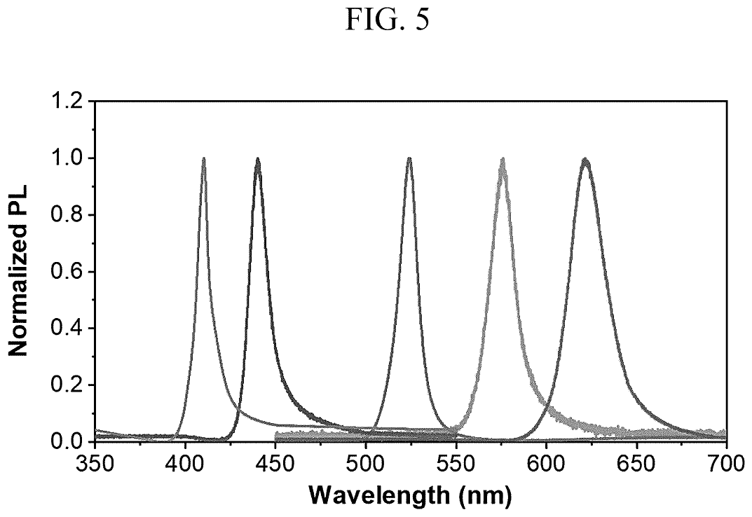

FIG. 5 is a view showing the emission peak according to n of the Ruddlesden-Popper perovskite according to an embodiment. In addition, the emission peak and a full width at half maximum (FWHM) according to n of the Ruddlesden-Popper perovskite according to an embodiment are shown in Table 1.

Specifically, through the emission peak and the full width at half maximum (FWHM) in Table 1 and FIG. 5, a light emitting material with various compositions capable of covering the entire visible light region may be secured by controlling n as well as using one type of halide as X.

TABLE 1

| | Photolumi- | Photolumi- |
|---|---|---|
| | nescence | nescence |
| | peak | FWHM |
| PEA₂PbBr₄ (X = Br, n = 1) | 409 nm | 11 nm |
| PEA₂MAPb₂Br₇ (X = Br, n = 2) | 440 nm | 13 nm |
| PEA₂PbI₄ (X = I, n = 1) | 524 nm | 14 nm |
| PEA₂MAPb₂I₇ (X = I, n = 2) | 575 nm | 19 nm |
| PEA₂MA₂Pb₃I₁₀ (X = I, n = 3) | 621 nm | 22 nm |

The Ruddlesden-Popper perovskite may be obtained in a state of a bulk single crystal layer in which isotropic growth has occurred, resulting in low electrical conductivity in a Z-axis. Accordingly, in order to apply the Ruddlesden-Popper perovskite bulk single crystal layer to a light-emitting device, it is necessary to make it into a thin film.

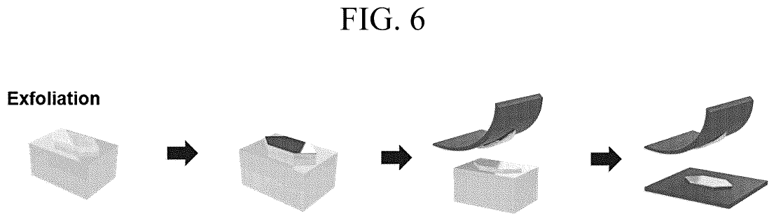

For this purpose, as shown in FIG. 6, the Ruddlesden-Popper perovskite bulk single crystal layer of an embodiment is exfoliated and transferred.

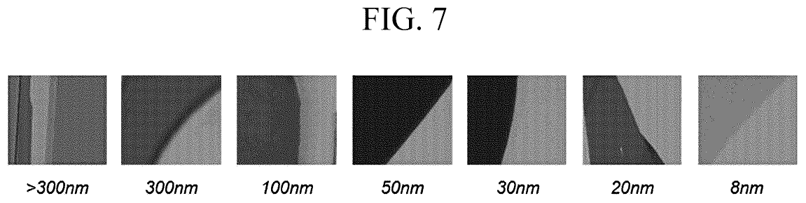

Herein, compared with a case of simply mechanically exfoliating the Ruddlesden-Popper perovskite bulk single crystal layer, in the case of transferring the Ruddlesden-Popper perovskite bulk single crystal layer onto a hydrophilic conductive polymer substrate and exfoliating it, the exfoliated Ruddlesden-Popper perovskite has a uniform thickness, uniform surface morphology, etc. Herein, as shown in FIG. 7, the exfoliated Ruddlesden-Popper perovskite single crystal layer exhibits color differences according to a thickness.

### Hydrophilic Conductive Polymer Substrate (Lower Substrate for Transfer)

Since the hydrophilic conductive polymer thin film is a rigid substrate, cracking of the Ruddlesden-Popper perovskite bulk single crystal layer transferred to the surface is suppressed.

Specifically, the hydrophilic conductive polymer substrate may include PEDOT:PSS, 3-Hydroxytyramine hydrochloride (DA·HCl), poly[bis(4-butypheny)-bis(phenyl)benzidine (poly-TPD), poly(9-vinylcarbazole) (PVK) as a hydrophilic conductive polymer; and NiOₓ, MoO₃, and Cu₂O as an inorganic material; or a combination thereof.

Additionally, the hydrophilic conductive polymer substrate may include γ-aminobutyric acid (GABA), zwitterion, 3-glycidyloxypropyl) trimethoxysilane (GOPS), or a combination thereof as an additive.

### Process of Transferring Two-Dimensional Material to Pixelated Template

Since the two-dimensional material has a layered structure and has soft mechanical properties, when the two-dimensional material is transferred to the pixelated template, the two-dimensional material on the concave portions is selectively removed, and a two-dimensional pixel array of material may be deposited on the convex portions.

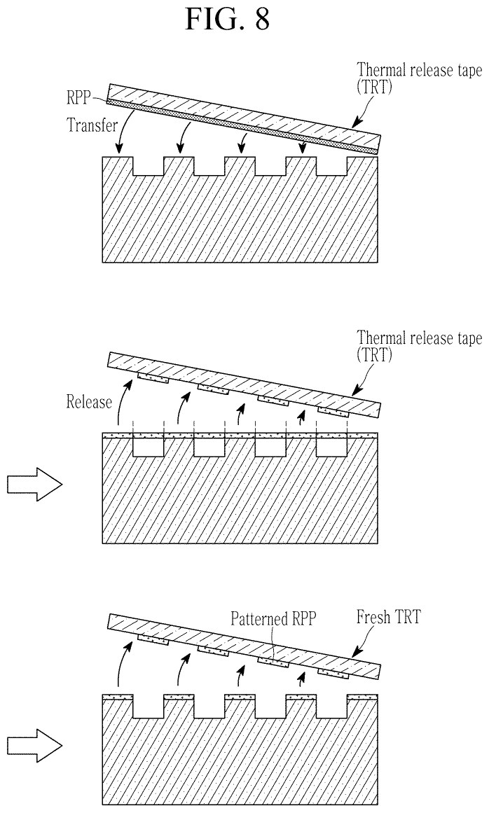

Specifically, FIG. 8 is a schematic view illustrating a process for transferring two-dimensional material to a pixelated template in an embodiment.

Referring to FIG. 8, the process may include transferring two-dimensional material to the pixelated template, thereby selectively removing the two-dimensional material on the concave portion and obtaining a first stack of two-dimensional material pixel arrays deposited on the convex portion, preparing a first adhesive substrate to which a two-dimensional material is attached; detaching the two-dimensional material from the first adhesive substrate and transferring it to the pixelated template.

The first adhesive substrate may include thermal release tape (TRT). The thermal release tape has strong adhesion at room temperature, which weakens at a high temperature (about 150° C.). Accordingly, if the thermal release tape is used as the first adhesive substrate, and the first adhesive substrate adhered with the two-dimensional material is heated, the two-dimensional material may be easily detached from the first adhesive substrate.

### Manufacturing Process of Light-Emitting Device

The process of manufacturing a light-emitting device may include detaching the two-dimensional material pixel array from the first stack and placing the two-dimensional material pixel array between a first electrode on which a first functional layer is deposited and a second electrode on which a second functional layer is deposited, transferring a first functional layer to the first stack, selectively removing the first functional layer on the concave portions, and obtaining a second stack in which a two-dimensional material pixel array and a first functional layer pixel array are sequentially deposited on the convex portions; transferring the first electrode to the second stack, selectively removing the first electrode on the concave portions, and obtaining a third stack in which a two-dimensional material pixel array, a first functional layer pixel array, and a first electrode pixel array are sequentially deposited on the convex portions; detaching the two-dimensional material pixel array, the first functional layer pixel array, and the first electrode pixel array from the third stack and transferring them onto the second electrode on which the second functional layer is deposited.

Using the pixelated template, the first functional layer and the first electrode can also be sequentially converted into a pixel array. As a result, the first electrode pixel array, the first functional layer pixel array, and the two-dimensional material pixel array can be perfectly aligned in the vertical direction.

The process may include detaching the two-dimensional material pixel array, the first functional layer pixel array, and the first electrode pixel array from the third stack and transferring them onto the second electrode on which the second functional layer is deposited, attaching a second adhesive substrate to the third stack; detaching the two-dimensional material pixel array, the first functional layer pixel array, and the first electrode pixel array from the second adhesive substrate and transferring them onto the second electrode on which the second functional layer is deposited.

Here, the second adhesive substrate, like the first adhesive substrate, may include a thermal release tape (TRT). The description for this is as described above.

### Second Functional Layer

The second functional layer to which the material pixel array, first functional layer pixel array, and first electrode pixel array are transferred may be a hole transport layer, and the hole transport layer may be a hydrophilic conductive polymer thin film.

The description of the hydrophilic conductive polymer thin film is the same as described above.

### (Light-Emitting Device)

Another embodiment provides a light-emitting device including a first electrode 1; a first functional layer 2 on the first electrode 1; a two-dimensional material pixel array 3 on the first functional layer 2; a second functional layer 4 on the two-dimensional material pixel array 3; and a second electrode 5 on the second functional layer 4.

FIGS. 1 to 3 are schematic views showing light-emitting devices manufactured according to embodiments, which includes both a forward structure and an inverse structure.

### Two-Dimensional Material Pixel Array

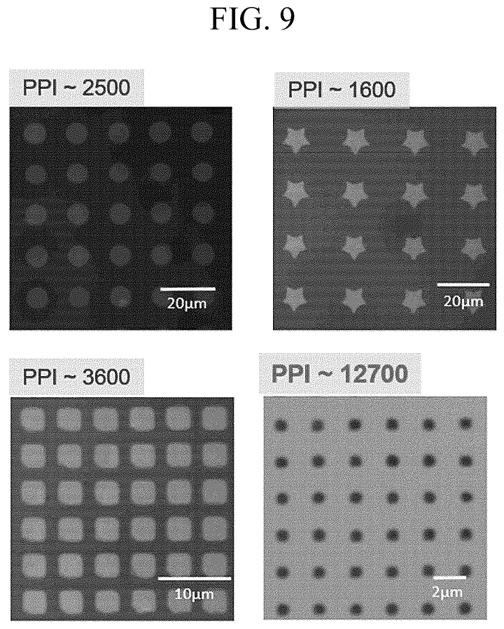

FIG. 9 is an OM photograph of a two-dimensional material pixel array according to an embodiment.

The two-dimensional material pixel array may have pixel density of about 1,000 to about 13,000 PPI, about 2,000 to about 13,000 PPI, or about 3,000 to about 13,000 PPI.

Accordingly, a highly integrated display may be implemented.

The two-dimensional material pixel array may have surface rms of about 1 Å or less and specifically, about 0.5 Å or less.

The two-dimensional material pixel array has a thickness of about 20 to about 30 nm.

If the two-dimensional material pixel array is the exfoliated Ruddlesden-Popper perovskite single crystal layer, there occur color differences depending on a thickness thereof. Accordingly, the two-dimensional material pixel array may function as a light emitting layer.

A pixel array shape of the two-dimensional material pixel array may be a dot, a circle, an oval, a polygon, a ring, or a combination thereof.

### First Functional Layer and Second Functional Layer

One of the first functional layer and the second functional layer may be an electron transport layer, and the other may be a hole transport layer.

The hole transport layer may be PEDOT:PSS, 3-hydroxytyramine hydrochloride (DA·HCl), poly[bis(4-butypheny)-bis(phenyl)benzidine (poly-TPD), and poly(9-vinylcarbazole) (PVK) as a hydrophilic conductive polymer; NiOₓ, MoO₃, and Cu₂O as an inorganic material; or a combination thereof. The hole transport layer may include γ-aminobutyric acid (GABA), Zwitterion, 3-glycidyloxypropyl) trimethoxysilane (GOPS), or a combination thereof as an additive.

The electron transport layer includes one selected from SnO₂, TiO₂, ZrO, Al₂O₃, ZnO, WO₃, Nb₂O₅, and TiSrO₃ as an inorganic material; phenyl-C61-butyric acid methyl ester (PCBM), 2,2′,2″-(1,3,5-benzinetriyl)-tris(1-phenyl-1-H-benzimidazole (TPBi), C60, bathocuproine (BCP), 4,6-bis(3,5-di(pyridin-3-yl)phenyl)-2-methylpyrimidine (B3PyMPM), tris(2,4,6-trimethyl-3-(pyridin-3-yl)phenyl) borane (3TPYMB), 2-(4-biphenyl)-5-(4-tert-butylphenyl)-134-oxadiazole (PBD), bis[2-(diphenylphosphino)phenyl]ether oxide (DPEPO) as an organic material; and combinations thereof, but is not limited thereof.

### First Electrode

The first electrode may include one selected from Al, Au, Ag, Pt, Ni, Cu, In, Ru, Pd, Rh, Mo, Ir, Os, C, a conductive polymer, and combinations thereof but is not limited thereto.

### Second Electrode

The second electrode may include one selected from FTO, ITO, IZO, ZnO—Ga₂O₃, ZnO—Al₂O₃, SnO₂—Sb₂O₃, and combinations thereof, but is not limited thereto.

### Pixel Arraying of the Constituent Layers

As in the above-described embodiment, using the pixelated template, the first functional layer and the first electrode can also be sequentially arrayed into pixels.

The first electrode is a first electrode pixel array, the first functional layer is a first functional layer pixel array, and the first electrode pixel array, the first functional layer pixel array, and the two-dimensional material pixel array are in line.

### Manufacturing Process of Perovskite Light-Emitting Device

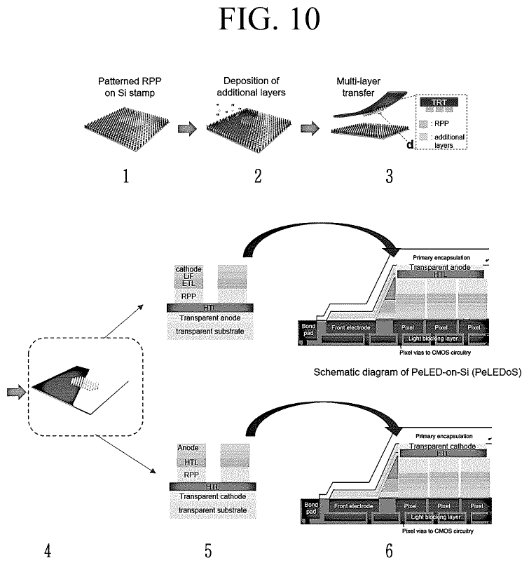

FIG. 10 is a process flowchart for manufacturing a perovskite light-emitting device according to an embodiment. Hereinafter, description will be given according to the serial numbers shown in FIG. 10.

1. As the ‘exfoliated Ruddlesden-Popper perovskite single crystal layer,’ which is a type of two-dimensional materials, is transferred onto a silicon (Si) templet, which is a type of the pixelated templet with a convex portion and a concave portion, the two-dimensional material on the concave portion is selectively removed, obtaining a first stack in which the two-dimensional material pixel array is deposited on the convex portion.

2. The first functional layer and first electrode are sequentially deposited on the single crystal layer transferred onto the pixelated template, obtaining a third stack that the two-dimensional material pixel array, the first functional layer pixel array, and the first electrode pixel array are sequentially deposited on the convex portion.

3. The third stack may be detached from the pixelated template by using a thermal release tape (TRT), which is a type of the second adhesive substrate.

4. The third stack adhered to the thermal release tape (TRT) is obtained.

5. The third stack may be detached from the thermal release tape (TRT) and transferred onto a second electrode deposited with a second functional layer (top: forward structure, bottom: inverse structure).

6. A perovskite light-emitting device manufactured according to 1 to 5 may be combined with a complementary metal-oxide-semiconductor (CMOS).

Hereinafter, examples of the present invention and comparative examples are described. The following examples are only examples of the present invention, but the present invention is not limited to the following examples.

### Example 1

### (1) Manufacturing of Pixelated Template

After coating a photoresist on a silicon substrate, a predetermined region thereof was exposed and developed to form a patterned photoresist layer. Subsequently, a DRIE (deep-reactive ion etching) dry etching process was performed to etch the exposed silicon surface and remove the photoresist, manufacturing a pixelated template with a negatively etched surface. Herein, the pixelated template was manufactured to have about 2560 PPI.

### (2) Transferring of Two-Dimensional Material (Manufacturing of First Stack)

A thermal release tape was used to exfoliate a bulk two-dimensional material a (bulk Ruddlesden-Popper perovskite single crystal layer). The two-dimensional material exfoliated by the release tape (the exfoliated Ruddlesden-Popper perovskite single crystal layer) was attached onto the pixelated template to exfoliate the release tape alone at a high temperature (about 150° C.) and transfer the two-dimensional material onto the pixelated template. The two-dimensional material was immediately pixelated, as soon as transferred onto the pixelated template.

### (3) Transferring of the First Functional Layer (Manufacturing of the Second Stack)

On the pixelated template onto which the two-dimensional material was transferred, 2,2′,2″-(1,3,5-Benzinetriyl)-tris(1-phenyl-1-H-benzimidazole) (TPBi) was vacuum-deposited as a first functional layer to manufacture a second stack.

### (4) Transferring of the First Electrode (Manufacturing of Third Stack)

On the second stack in which the two-dimensional material and the first functional layer were sequentially stacked, LiF (lithium fluoride) and Al (aluminum) as a first electrode were sequentially vacuum-deposited to manufacture a third stack.

(5) Manufacturing of Second Electrode on which the Second Functional Layer is Deposited

On a separate substrate deposited with patterned ITO (Indium tin oxide) as a second electrode, poly(3,4-ethylenedioxythiophene) polystyrene sulfonate (PEDOT:PSS) as a second functional layer was deposited through a solution process in a vacuum deposition method to form a stacked structure of the second functional layer/the second electrode.

### (6) Final Assembly Process

After detaching the stacked structure of the first electrode/the first functional layer/the two-dimensional material from the third stack by using a thermal release tape and then, attaching it onto the stacked structure of the second functional layer/the second electrode, the thermal release tape alone was exfoliated at a high temperature (about 150° C.) to obtain a final device structure. The obtained final device structure was a stacked structure of the first electrode/the first functional layer/the two-dimensional material/the second functional layer/the second electrode.

### Example 2

A light-emitting device was manufactured in the same manner as in Example 1 except that PPI of the pixelated template was changed to about 1500.

### Example 3

A light-emitting device was manufactured in the same manner as in Example 1 except that PPI of the pixelated template was changed to about 1000.

### Comparative Example 1

A bulk two-dimensional material (a bulk Ruddlesden-Popper perovskite single crystal layer) was exfoliated by using a thermal release tape.

Independently, on ITO (Indium tin oxide) as a second electrode, poly(3,4-ethylenedioxythiophene) polystyrene sulfonate (PEDOT:PSS) was deposited as a second functional layer in a solution process method.

Onto the surface of the second electrode deposited with the second functional layer, the exfoliated two-dimensional material (exfoliated Ruddlesden-Popper perovskite single crystal layer) was transferred.

On the peeled two-dimensional material layer, 2,2′,2″-(1,3,5-Benzinetriyl)-tris(1-phenyl-1-H-benzimidazole) (TPBi) as a first functional layer was vacuum-deposited, and LiF (lithium fluoride)/Al (aluminium) as a first electrode were vacuum-deposited to obtain a final device structure.

### Evaluation Example 1: Evaluation of Two-Dimensional Material Pixel Array

The two-dimensional material pixel arrays according to Examples 1 to 3 and the two-dimensional material layer according to Comparative Example 1 were evaluated in the following methods, and the evaluation results are shown in Table 2.

(1) Pixel Density: The pixel density of each two-dimensional material pixel array was calculated by counting the number of pixels per inch in a diagonal direction of each pixel array.

(2) Surface rms: Surface rms in a pixel region of each two-dimensional material pixel array was measured by using AFM (atomic force microscope) and Park NX-10 (Park systems).

(3) Thickness: A thickness was measured by a difference between the pixel region and a bottom surface of each two-dimensional material pixel array by using AFM (atomic force microscope) and Park NX-10 (Park systems).

TABLE 2

| | Pixel density | Surface rms | Thickness |
|---|---|---|---|
| | (PPI) | (Å) | (nm) |
| Example 1 | about 2560 | <0.5 Å | about 10 nm |
| Example 2 | about 1500 | <0.5 Å | about 15 nm |
| Example 3 | about 1000 | <0.5 Å | about 15 nm |
| Comparative Example 1 | 1 | <0.5 Å | about 10 nm |

### Evaluation Example 2: Evaluation of Light-Emitting Device

The light-emitting devices of Examples 1 to 3 and Comparative Example 1 were evaluated in the following methods, and the results are shown in Table 3.

Current density: The current density was based on the current density flowing when a voltage of 5V was applied to the light-emitting device.

Turn-on light emission intensity: The electroluminescence intensity emitted at a voltage of about 5V, at which light is emitted from the light-emitting device, was measured.

Full width at half maximum (FWHM) of the emission spectrum: The spectrum emitted from the light-emitting device was measured, and the FWHM of the spectrum was shown.

TABLE 3

| | Current | Turn-on emission | Photoluminescence full |
|---|---|---|---|
| | density | intensity | width at half maximum |
| | (mA/cm²) | (W/m² sr) | (FWHM) (nm) |
| Example 1 | 26.60 | 2 × 10⁻³ | 11 |
| Example 2 | 4.60 | 2.8 × 10⁻⁴ | 11 |
| Example 3 | 0.214 | 8.15 × 10⁻⁵ | 11 |
| Comparative | 0.06 | 1.39 × 10⁻³ | 11 |
| Example 1 | | | |

### SUMMARY

The pixelated light-emitting device according to an embodiment was confirmed to realize a pixelated light-emitting device with high pixel density.

Furthermore, as pixel density of the light-emitting device was increased, current density and turn-on emission intensity were more improved.

Although the preferred embodiments of the present invention have been described above, the present invention is not limited thereto, it is possible to implement various modifications within the scope of the claims, the detailed description of the invention, and the accompanying drawings, and it is natural that this also falls within the scope of the present invention.

### DESCRIPTION OF SYMBOLS

1: first electrode
2: first functional layer
3: two-dimensional material pixel array
4: second functional layer
5: second electrode

What is claimed is:

1. A method for manufacturing a light-emitting device, comprising
preparing a pixelated template having convex portions and concave portions;
transferring two-dimensional material to the pixelated template, thereby selectively removing the two-dimensional material on the concave portions and obtaining a first stack of two-dimensional material pixel arrays deposited on the convex portions; and
detaching the two-dimensional material pixel array from the first stack and placing the two-dimensional material pixel array between a first electrode on which a first functional layer is deposited and a second electrode on which a second functional layer is deposited.

2. The method of claim 1, wherein
the pixelated template is a silicon substrate having convex portions and concave portions.

3. The method of claim 2, wherein
the pixelated template is manufactured by
coating photoresist on a silicon substrate;
exposing a selective region of the photoresist through photolithography;
removing photoresist from the exposed region; and
removing the photoresist in the exposed region and then etching the photoresist in the remaining region.

4. The method of claim 1, wherein
the two-dimensional material includes an exfoliated Ruddlesden-Popper perovskite single crystal layer, graphene, bulk graphene, mica, molybdenum disulfide (MoS₂), or a combination thereof.

5. The method of claim 4, wherein
the exfoliated Ruddlesden-Popper perovskite single crystal layer is represented by Chemical Formula 1:
R₂Aₙ₋₁PbₙX₃ₙ₊₁ [Chemical Formula 1]
wherein, in Chemical Formula 1,
R is a C1 to C30 alkyl ammonium cation;
A is a cation selected from a methylammonium cation (MA⁺), a formamidinium cation (FA⁺), and a cesium cation (Cs⁺);
X is a halogen selected from I, Br, and Cl; and
n is an integer from 1 to 10.

6. The method of claim 4, wherein
the exfoliated Ruddlesden-Popper perovskite single crystal layer is manufactured by
transferring a Ruddlesden-Popper perovskite (RPP) bulk single crystal layer onto a hydrophilic conductive polymer substrate; and
exfoliating the transferred Ruddlesden-Popper perovskite bulk single crystal layer to form an exfoliated Ruddlesden-Popper perovskite single crystal layer.

7. The method of claim 1, wherein
transferring two-dimensional material to the pixelated template, thereby selectively removing the two-dimensional material on the concave portions and obtaining a first stack of two-dimensional material pixel arrays deposited on the convex portions,
preparing a first adhesive substrate to which a two-dimensional material is attached; and
detaching the two-dimensional material from the first adhesive substrate and transferring it to the pixelated template.

8. The method of claim 7, wherein
the first adhesive substrate includes a thermal release tape.

9. The method of claim 1, wherein
detaching the two-dimensional material pixel array from the first stack and placing the two-dimensional material pixel array between a first electrode on which a first functional layer is deposited and a second electrode on which a second functional layer is deposited,
transferring a first functional layer to the first stack, selectively removing the first functional layer on the concave portions, and obtaining a second stack in which a two-dimensional material pixel array and a first functional layer pixel array are sequentially deposited on the convex portions;
transferring the first electrode to the second stack, selectively removing the first electrode on the concave portions, and obtaining a third stack in which a two-dimensional material pixel array, a first functional layer pixel array, and a first electrode pixel array are sequentially deposited on the convex portions; and
detaching the two-dimensional material pixel array, the first functional layer pixel array, and the first electrode pixel array from the third stack and transferring them onto the second electrode on which the second functional layer is deposited.

10. The method of claim 9, wherein
detaching the two-dimensional material pixel array, the first functional layer pixel array, and the first electrode pixel array from the third stack and transferring them onto the second electrode on which the second functional layer is deposited,
attaching a second adhesive substrate to the third stack; and
detaching the two-dimensional material pixel array, the first functional layer pixel array, and the first electrode pixel array from the second adhesive substrate and transferring them onto the second electrode on which the second functional layer is deposited.

11. The method of claim 10, wherein
the second adhesive substrate includes a thermal release tape.

12. The method of claim 10, wherein
the second functional layer is a hole transport layer, and
the hole transport layer is a hydrophilic conductive polymer thin film.

13. The method of claim 12, wherein
the hole transport layer includes,
PEDOT:PSS, 3-hydroxytyramine hydrochloride (DA·HCl), poly[bis(4-butypheny)-bis(phenyl)benzidine (poly-TPD), and poly(9-vinylcarbazole) (PVK) as hydrophilic conductive polymer;
NiOₓ, MoO₃, and Cu₂O as an inorganic material;
a combination thereof.

14. The method of claim 13, wherein
the hole transport layer includes γ-aminobutyric acid (GABA), zwitterion, 3-glycidyloxypropyl) trimethoxysilane (GOPS), or a combination thereof as an additive.

15. A light-emitting device, comprising
a first electrode;
a first functional layer on the first electrode;
a two-dimensional material pixel array on the first functional layer;
a second functional layer on the two-dimensional material pixel array; and
a second electrode on the second functional layer.

16. The light-emitting device of claim 15, wherein
the two-dimensional material pixel array has a pixel density of about 1,000 to about 13,000 PPI.

17. The light-emitting device of claim 15, wherein
the two-dimensional material pixel array has a surface rms of less than or equal to about 1 Å.

18. The light-emitting device of claim 15, wherein
the two-dimensional material pixel array has a thickness of about 20 to about 30 nm.

19. The light-emitting device of claim 15, wherein
a pixel array shape of the two-dimensional material pixel array is a dot, a circle, an oval, a polygon, a ring, or a combination thereof.

20. The light-emitting device of claim 15, wherein
the first electrode is a first electrode pixel array,
the first functional layer is a first functional layer pixel array, and
the first electrode pixel array, the first functional layer pixel array, and the two-dimensional material pixel array are aligned in line.
